(19) United States
(12) Patent Application Publication
(10) Pub. No.: US 2025/0300034 A1
(43) Pub. Date: Sep. 25, 2025

(54) HARD DRIVE DEVICE AND THE HEAT DISSIPATION UNIT FOR A HARD DRIVE DEVICE

(71) Applicant: Innodisk Corporation, New Taipei (TW)

(72) Inventor: Shuang Te Chang, New Taipei (TW)

(21) Appl. No.: 18/800,334

(22) Filed: Aug. 12, 2024

(30) Foreign Application Priority Data
Mar. 20, 2024 (TW) 113110257

(51) Int. Cl. H01L 23/367; H01L 23/053; H01L 25/065; H01L 25/10; H05K 1/14; H05K 1/18

(52) U.S. Cl. CPC H01L 23/367; H01L 23/053; H01L 25/0652; H01L 25/105; H05K 1/144; H05K 1/181; H01L 2225/1052; H05K 2201/042; H05K 2201/10356; H05K 2201/10818

(57) ABSTRACT

A heat dissipation unit for a hard drive device is disclosed. The hard drive device has a housing and a plurality of internal heat-generating electronic components, a distance exists between at least one of the plurality of internal heating electronic components and the housing, the housing has an inner surface and an outer surface, and the heat dissipation unit is an intermediate extension member contacting at least one of the plurality of internal heat-generating electronic components, and extending beyond the inner surface.

### CROSS REFERENCE TO RELATED APPLICATION

This application claims the benefit of the Taiwan Patent Application No. 113110257, filed on Mar. 20, 2024, at the Taiwan Intellectual Property Office, the disclosure of which is incorporated herein in its entirety by reference.

### TECHNICAL FIELD

The present disclosure is related to a hard drive device and a heat dissipation unit for a hard drive device, in particular to a hard drive device and a heat dissipation unit for electronic components of the hard drive device.

### BACKGROUND

Current heat dissipation methods of hard drive devices include methods such as enhancing heat convection and increasing contact with the housing to dissipate heat. For the method to enhance heat convection, heat sinks and airflow are used to dissipate the heat from electronic components. This method can add a cooling fan to the heat sink to enhance the circulation of air to discharge the hot air out of the case, but it also requires the housing to have a configuration of intake airflow holes and exhaust airflow holes to improve heat dissipation efficiency. Therefore, the heat dissipation of electronic components will also be affected by the location of the airflow holes. For the method to increase contact with the housing to dissipate heat, the heat can be dissipated by contacting a large area of electronic components with the housing. For example, the surfaces of various chips can contact the housing, and the housing can be a metal housing made of a heat-dissipating material or can be a housing with a heat dissipation effect to facilitate heat dissipation. However, for electronic components in the middle of or inside the hard drive device, they may not be able to contact the housing of the hard drive device, and the positions of the thermal airflow holes in the housing may not be beneficial to the airflow of the chips in the middle of or inside the hard drive device.

### SUMMARY OF INVENTION

In view of the above-mentioned drawbacks in the prior art, the present invention proposes a heat dissipation unit including a heat dissipation body, which is disposed in a hard drive device and has an extension portion that can extend to the housing of the hard drive device. The heat dissipation body has a first distance from the housing of the disk drive device and is in contact with the electronic component. The electronic component has a second distance from the housing of the hard drive device. The extension portion can contact the housing to increase contact with the housing to dissipate heat. The extension portion can also form a vent without contacting the casing to enhance convection for heat dissipation.

In one embodiment, the present disclosure proposes a heat dissipation unit having an extension portion and a heat dissipation unit body. The heat dissipation unit body is not in contact with the housing, and the extension portion can extend beyond the inner surface of the housing or within the inner surface, the heat dissipation unit body can conduct the heat of the electronic components to the extension portion, and the extension portion can circulate hot air and dissipate heat to the outside of the housing without contacting the housing or without forming a closed housing with the housing.

In one embodiment, the present disclosure proposes a heat dissipation unit having an extension portion and a heat dissipation unit body. The heat dissipation unit body is not in contact with the housing, and the heat dissipation unit body can conduct the heat of the electronic components to the extension portion on condition that the extension portion is in contact with the housing to form a closed housing. In addition, the heat can be conducted to the housing on condition that the extension portion forms a closed housing by contacting the housing, and the extension portion itself can also be used as a housing to facilitate heat dissipation.

In one embodiment, the present disclosure proposes a heat dissipation unit having an extension portion and a heat dissipation unit body. The heat dissipation unit body is not in contact with the housing, and the extension portion can be arranged around the outer edge of the heat dissipation body of the heat dissipation unit, and the heat dissipation unit body is not in contact with the housing. The extension portion can extend beyond the inner surface of the housing, or within the inner surface. The heat dissipation unit body can conduct the heat of the electronic components to the extension portion, and the hot air can be circulated to dissipate heat to the outside of the housing on condition that the extension portion does not contact the housing or does not form a closed housing with the housing. Alternatively, on condition that the extension portion contacts the housing to form a closed housing, the heat dissipation unit body can conduct the heat of the electronic component to the extension portion, and the heat can be conducted to the housing on condition that a closed housing is formed by contacting the extension portion with the housing. The extension portion itself can also serve as a housing to facilitate heat dissipation.

In accordance with one aspect of the present disclosure, a hard drive device is disclosed. The hard drive device comprises a device body, a first housing, a second housing, a heat dissipation unit and at least one electronic component. The first housing is configured on the device body. The second housing is configured opposite to the first housing. The heat dissipation unit has a first surface, a second surface, a first extension element and a second extension element. The at least one electronic component is in contact with at least one of the first surface and the second surface, wherein the first extension element is in contact with the first housing and the second housing, and the second extension element is in contact with the first housing and the second housing; and the first extension element and the second extension element serve as a third housing of the hard drive device.

In accordance with another aspect of the present disclosure, a heat dissipation unit for a hard drive device is disclosed, wherein the hard drive device includes a device printed circuit board, a first and a second heat-generating electronic components respectively disposed on both sides of the printed circuit board, and a housing in contact with the first heat-generating electronic components; the housing has an inner surface and an outer surface; a distance exists between the second heat-generating electronic components and the inner surface; and the heat dissipation unit comprises a heat dissipation unit body in contact with the second heat-generating electronic component and extends beyond the inner surface.

In accordance with a further aspect of the present disclosure, a heat dissipation unit for a hard drive device is disclosed, wherein the hard drive device has a housing and a plurality of internal heat-generating electronic components; a distance exists between at least one of the plurality of internal heating electronic components and the housing; the housing has an inner surface and an outer surface; and the heat dissipation unit is an intermediate extension member contacting with at least one of the plurality of internal heat-generating electronic components and extending beyond the inner surface.

Since electronic components, such as chips, are deep inside the electronic device without contacting the housing, and the positions of the heat dissipation vents may also be unfavorable for heat dissipation of the chips in the middle of or inside the electronic device, through the hard drive device and its heat dissipation unit of the present disclosure, the heat transfer efficiency can be enhanced, and the airflow ventilation can also be increased to strengthen heat dissipation capacity.

In addition, the traditional heat dissipation unit of the hard drive device cannot dissipate the heat of the chip that is deep inside the hard drive device without contacting the heat sink or the housing. However, the heat dissipation unit proposed in the present disclosure can dissipate the heat of the chip that is deep inside the hard drive device without contacting the heat sink or the housing.

The above embodiments and advantages of the present disclosure will become more readily apparent to those ordinarily skilled in the art after reviewing the following detailed descriptions and accompanying drawings:

### BRIEF DESCRIPTION OF THE DRAWINGS

FIG. 1 is a schematic diagram of a hard drive device according to a preferred embodiment of the present disclosure;

FIG. 2 is a schematic diagram of a hard drive device according to another preferred embodiment of the present disclosure;

FIG. 3A is a schematic diagram of the extension element of the heat dissipation unit extending beyond the corners of the heat dissipation device according to the preferred embodiment of the present disclosure;

FIG. 3B is a schematic diagram of another embodiment of FIG. 3A;

FIG. 4 is a schematic diagram of a heat dissipation unit having an opening according to a preferred embodiment of the present disclosure;

FIG. 5 is a schematic diagram of a heat dissipation unit having an opening according to another preferred embodiment of the present disclosure;

FIG. 6 is a schematic diagram of a hard drive device according to another preferred embodiment of the present disclosure;

FIG. 7 is a schematic diagram of the heat dissipation unit for the hard drive device according to the preferred embodiment of the present disclosure;

FIG. 8A is a schematic diagram of a heat dissipation unit for a hard drive device according to another preferred embodiment of the present disclosure;

FIG. 8B is a schematic diagram of another embodiment of the heat dissipation unit according to FIG. 8A;

FIG. 8C is a schematic diagram of another embodiment of the heat dissipation unit according to FIG. 8B;

FIG. 9A is a schematic diagram of a heat dissipation unit for a hard drive device according to another preferred embodiment of the present disclosure;

FIG. 9B is a schematic diagram of another embodiment of the heat dissipation unit according to FIG. 9A; and

FIG. 9C is a schematic diagram of another embodiment of the heat dissipation unit according to FIG. 9B.

### DETAILED DESCRIPTION OF THE PREFERRED EMBODIMENTS

Please read the following detailed description with reference to the accompanying drawings of the present disclosure. The accompanying drawings of the present disclosure are used as examples to introduce various embodiments of the present disclosure and to understand how to implement the present disclosure. The embodiments of the present disclosure provide sufficient content for those skilled in the art to implement the embodiments of the present disclosure, or implement embodiments derived from the content of the present disclosure. It should be noted that these embodiments are not mutually exclusive from each other, and some embodiments can be appropriately combined with another one or more embodiments to form new embodiments; that is, the implementation of the present disclosure is not limited to the examples disclosed below. In addition, for the sake of brevity and clarity, relevant details are not excessively disclosed in each embodiment, and even if specific details are disclosed, examples are used only to make readers understand. The present invention will now be described more specifically with reference to the following embodiments. It is to be noted that the following descriptions of the preferred embodiments of this invention are presented herein for the purposes of illustration and description only; they are not intended to be exhaustive or to be limited to the precise form disclosed.

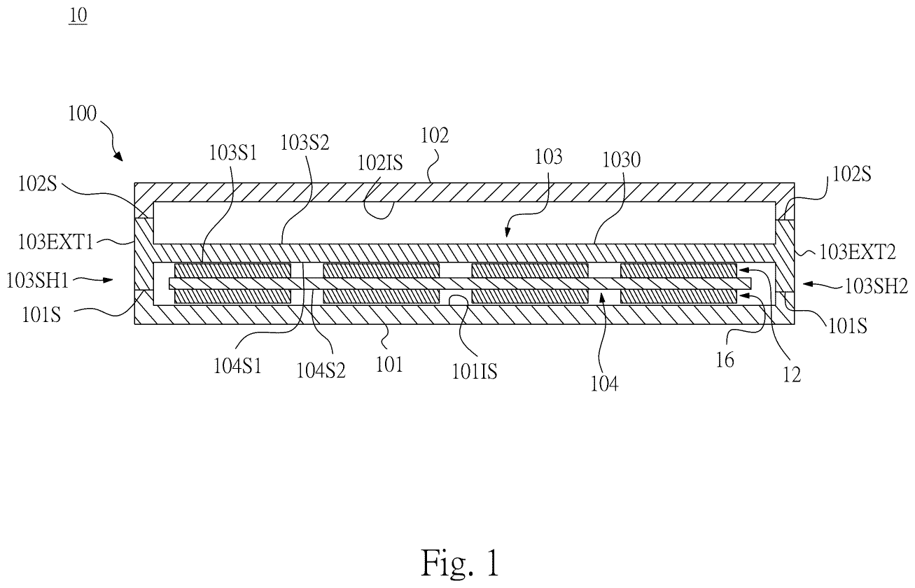

Please refer to FIG. 1, which is a schematic diagram of a hard drive device 10 according to a preferred embodiment of the present disclosure. The hard drive device 10 includes a device body 100, a first housing 101, a second housing 102, a heat dissipation unit 103 and at least one electronic component 12. The first housing 101 is configured on the device body 100, and has a first connection surface 101S. The second housing 102 has a second connection surface 102S, and is configured opposite to the first housing 101. The heat dissipation unit 103 has a first surface 103S1, a second surface 103S2, a first extension element 103EXT1 and a second extension element 103EXT2. The at least one electronic component 12 is in direct or indirect contact with the first surface 103S1 to conduct the heat of the at least one electronic component 12 from the at least one electronic component 12 to the heat dissipation unit 103. The first extension element 130EXT1 is in direct or indirect contact with the first connection surface 101S and the second connection surface 102S, and the second extension element 103EXT2 is in direct or indirect contact with the first connection surface 101S and the second connection surface 102S so as to conduct the heat from the first surface 103S1 of the heat dissipation unit 103 to the first extension element 103EXT1 and the second extension element 103EXT2. The first extension element 103EXT1 and the second extension element 103EXT2 serve as a third housing 103SH1, 103SH2 of the hard drive device 10 so as to dissipate the heat by the third housing 103SH1, 103SH2.

In any embodiment of the present disclosure, the hard drive device 10 further includes a printed circuit board (PCB) 104, which has a PCB surface 104S1 and a PCB surface 104S2. At least one electronic component 12 is disposed on the PCB surface 104S1, and electrically connected to the PCB 104. Another at least one electronic component 16 is disposed on the PCB surface 104S2, and also electrically connected to the PCB 104. However, the other side of the another at least one electronic component 106 contacts an inner surface 101IS of the first housing 101. The heat dissipation unit 103 has a heat dissipation unit body 1030, and the heat dissipation unit body 1030 is at a distance from both the first housing 101 and the second housing 102 without contacting them.

All hard drive devices in the present disclosure can be electronic hard drive devices, such as solid state drives SSD, NVME M.2 hard drive devices, magnetic resistive hard drive devices, or mechanical hard drive devices, such as hard drive devices having mechanical read-write arms and storage disks, etc. Preferably, the hard drive device is an electronic hard drive device.

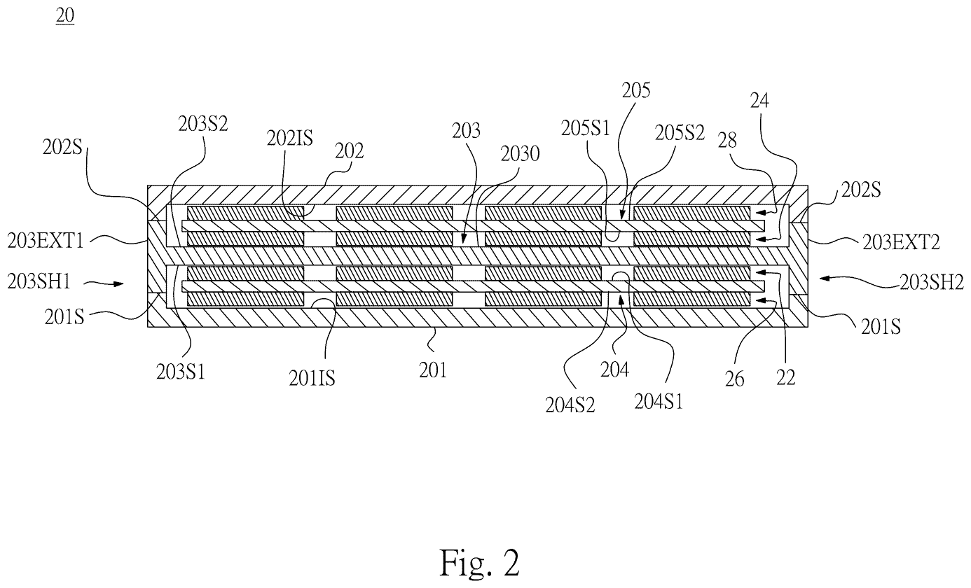

Please refer to FIG. 2, which is a schematic diagram of a hard drive device 20 according to another preferred embodiment of the present disclosure. The hard drive device 20 includes a first housing 201, a second housing 202, a heat dissipation unit 203 and at least one electronic component 22, 24. The first housing 201 has a first connection surface 201S. The second housing 202 has a second connection surface 202S, and is disposed at a corresponding position of the first housing 201. The heat dissipation unit 203 has a first surface 203S1, a second surface 203S2, a first extension element 203EXT1 and a second extension element 203EXT2. The at least one electronic component 22 is in direct or indirect contact with the first surface 203S1 to conduct heat of the at least one electronic component 22 from the at least one electronic component 22 to the heat dissipation unit 203, and the at least one electronic component 24 is in direct or indirect contact with the second surface 203S2 to conduct heat of the at least one electronic component 24 from the at least one electronic component 24 to the heat dissipation unit 203. The first extension element 203EXT1 is in direct or indirect contact with the first connection surface 201S and the second connection surface 202S, and the second extension element 203EXT2 is in direct or indirect contact with the first connection surface 201S and the second connection surface 202S so as to conduct the heat from the first surface 203S1 of the heat dissipation unit 203 to the first extension element 203EXT1 and the second extension element 203EXT2. The first extension element 203EXT1 and the second extension element 203EXT2 serve as a third housing 203SH1, 203SH2 of the hard drive device 20 so as to dissipate the heat through the third housing 203SH1, 203SH2.

In any embodiment of the present disclosure, the hard drive device 20 further includes a printed circuit board (PCB) 204, 205. The PCB 204 has a PCB surface 204S1 and a PCB surface 104S2. The PCB 205 has a PCB surface 205S1 and a PCB surface 105S2. At least one electronic component 22, 24 is respectively configured on the PCB surface 204S1, the PCB surface 205S1, and respectively electrically connected to the PCB 204, the PCB 205. Another at least one electronic component 26, 28 is respectively configured on the PCB surface 204S2, the PCB surface 205S2, and respectively electrically connected to the PCB 204, the PCB 205. However, the other side of the another at least one electronic component 26 and 28 is respectively in contact with an inner surface 201IS of the first housing 201 and an inner surface 202IS of the second housing 202. The heat dissipation unit 203 has a heat dissipation unit body 2030, and the heat dissipation unit body 2030 is at a distance from both the first housing 201 and the second housing 202 without contacting them.

In any embodiment of the present disclosure, the at least one electronic component 12, 16, 22, 24, 26, 28 is a heat-generating electronic component, which includes at least one of a processor chip, a memory chip, a power management chip, a communication chip and an application specific integrated circuit (ASIC). There is a first heat conduction element (not shown) between the heat dissipation unit 103, 203 and the at least one electronic component 12, 16, 22, 24, 26, 28. There is a second heat conduction element (not shown) between the first extension element 103EXT1, 203EXT1 of the heat dissipation unit 103, 203 and the first connection surface 101S, 201S and the second connection surface 102S. There is the second heat conductive element between the second extension element 103EXT2, 203EXT2 of the heat dissipation unit 103, 203 and the first connection surface 101S, 201S and the second connection surface 102S, 202S. The first heat conduction element and the second heat conduction element include a heat dissipation medium. The first surface 103S1, 203S1 and the second surface 103S2, 203S2 of the heat dissipation unit 103, 203 are not in contact with the first housing 101, 201 and the second housing 102, 202. The first extension element 103EXT1, 203EXT1 and the second extension element 103EXT2, 203EXT2 may be elements made of different materials from the heat dissipation body 1030, 2030, or elements made of the same material as the heat dissipation body 1030, 2030 (for example, integrally formed elements). The first extension element 103EXT1, 203EXT1 and the second extension element 103EXT2, 203EXT2 are integrally formed in the heat dissipation unit 103, 203. For example, the heat dissipation unit 103, the first extension element 103EXT1, 203EXT1 and the second extension element 103EXT2, 203EXT2 are integrally formed; that is, the first extension element 103EXT1, 203EXT1 and the second extension element 103EXT2, 203EXT2 are part of the heat dissipation unit 103, 203, rather than additional elements. The first extension element 103EXT1, 203EXT1 and the second extension element 103EXT2, 203EXT2 of the heat dissipation unit 103, 203 are disposed between the first housing 101, 201 and the second housing 102, 202.

In any embodiment of the present disclosure, the first extension element 103EXT1, 203EXT1 and the second extension element 103EXT2, 203EXT2 may be in contact with both of the first housing 101, 201 and the second housing 102, 202 to increase the heat dissipation effect. Alternatively, the first extension element 103EXT1, 203EXT1 and the second extension element 103EXT2, 203EXT2 may be in contact with one of the first housing 101, 201 and the second housing 102, 202. The first extension element 103EXT1, 203EXT1 and the second extension element 103EXT2, 203EXT2 can also form a vent without contacting the housings to enhance convection for heat dissipation. However, in the embodiment in which the first extension element 103EXT1, 203EXT1 and the second extension element 103EXT2, 203EXT2 are not in contact with the housings, other parts of the heat dissipation unit 103, 203 can also be designed to be in contact with the housings to support the heat dissipation unit 103, 203.

In any embodiment of the present disclosure, the heat dissipation unit body 1030, 2030 is not in contact with the first housing 101, 201 and the second housing 102, 202, and the first extension element 103EXT1, 203EXT1 and the second extension elements 103EXT2, 203EXT2 may extend beyond the inner surfaces 101IS, 201IS of the first housing 101, 201 and the inner surfaces 102IS, 202IS of the second housing 102, 202 respectively, or may be within the inner surfaces 101IS, 201IS, 102IS, 202IS. The heat dissipation unit body 1030, 2030 can conduct the heat of the electronic components 12, 16, 22, 24, 26, 28 to the first extension element 103EXT1, 203EXT1 and the second extension element 103EXT2, 203EXT2. In addition, under the condition that the first extension element 103EXT1, 203EXT1 and the second extension element 103EXT2, 203EXT2 do not contact the first housing 101, 201 and the second housing 102, 202, or do not form a closed housing with the first housing 101, 201 and the second housing 102, 202, the hot air can be circulated to dissipate heat to the outside of the housings.

In any embodiment of the present disclosure, the heat dissipation unit body 1030, 2030 is not in contact with the first housing 101, 201 and the second housing 102, 202, and an annular extension element can be arranged around the outer edge of the heat dissipation unit body 1030, 2030; that is, the first extension element 103EXT1, 203EXT1 and the second extension element 103EXT2, 203EXT2 in FIGS. 1 and 2 are regarded as an annular extension element, and the annular extension element can extend beyond the inner surface 101IS, 201IS of the first housing 101, 201 and/or extend beyond the inner surface 102IS, 202IS of the second housing 102, 202, or is within the inner surface 101IS, 201IS, 102IS, 202IS. The heat dissipation unit body 1030, 2030 can conduct the heat of the electronic components 12, 16, 22, 24, 26, 28 to the annular extension element. In addition, under the condition that the annular extension element does not contact the first housing 101, 201 and the second housing 102, 202, or does not form a closed housing with the first housing 101, 201 and the second housing 102, 202, the hot air can be circulated to dissipate heat to the outside of the housings. Alternatively, under the condition that the annular extension element is in contact with the first housing 101, 201 and the second housing 102, 202 to form a closed housing, the heat dissipation unit body 1030, 2030 can conduct the heat of the electronic components 12, 16, 22, 24, 26, 28 to the annular extension element. Under the condition that the annular extension element contacts the first housing 101, 201 and the second housing 102, 202 to form a closed housing, the heat can be conducted to the first housing 101, 201 and the second housing 102, 202. Moreover, the annular extension element itself can also be used as a housing to facilitate heat dissipation.

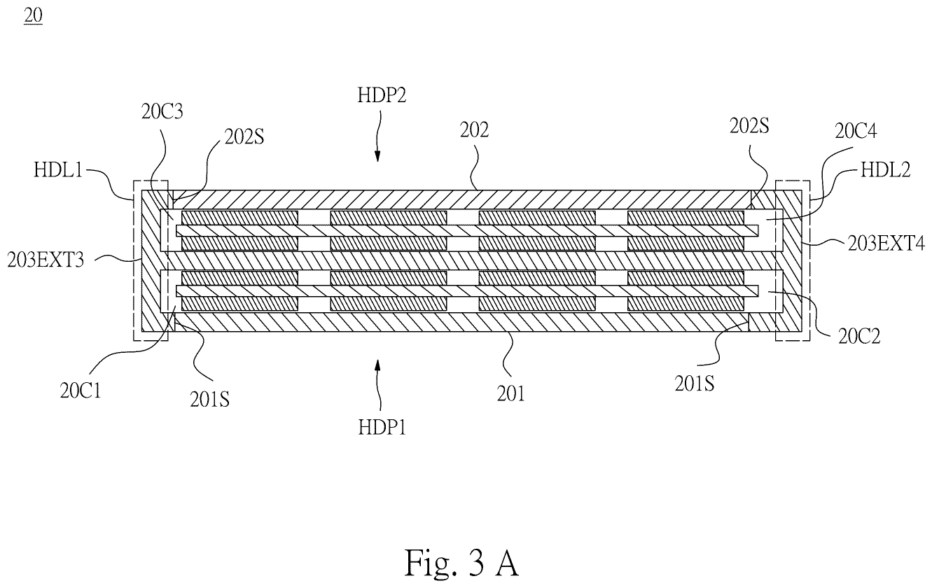

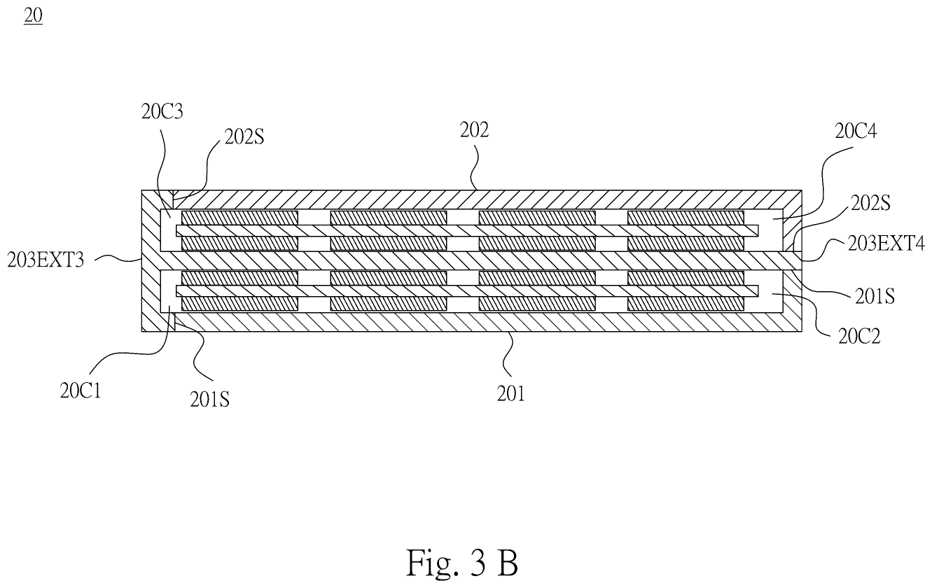

Please refer to FIG. 3A, which is a schematic diagram of the extension element of the heat dissipation unit 203 extending beyond the corners of the heat dissipation device 20 according to the preferred embodiment of the present disclosure. The hard drive device 20 has a first corner 20C1 and a second corner 20C2. The extension element 203EXT3 extends beyond the first corner 20C1 and contacts the first connection surface 201S of the first housing 201. The extension element 203EXT4 extends beyond the second corner 20C2, and contacts the first connection surface 201S of the first housing 201. The hard drive device 20 has a third corner 20C3 and a fourth corner 20C4. The extension element 203EXT3 extends beyond the third corner 20C3, and contacts the second connection surface 202S of the second housing 202. The extension element 203EXT4 extends beyond the fourth corner 20C4, and contacts the second connection surface 202S of the second housing 202.

Please refer to FIG. 3B, which is a schematic diagram of another embodiment of FIG. 3A. The extension element 203EXT3 and the extension element 203EXT4 can be asymmetrical; for example, they can have different extension ranges. For example, the extension element 203EXT3 extends beyond the first corner 20C1 and the third corner 20C3, while the extension element 203EXT4 does not extend, or does not extend beyond the second corner 20C2 and the fourth corner 20C4. Certainly, the extension element 203EXT3, 203EXT4 can also extend only to the first housing 201, or only to the second housing 202.

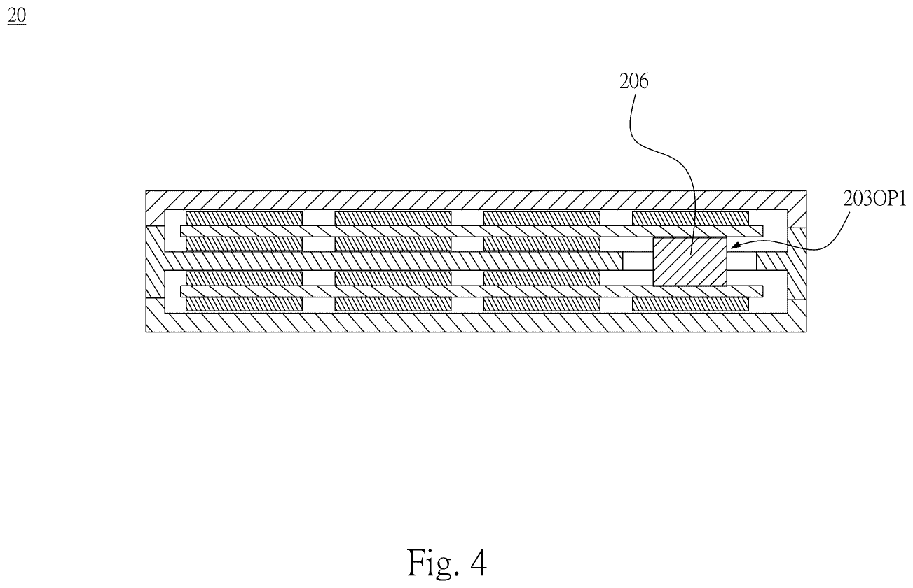

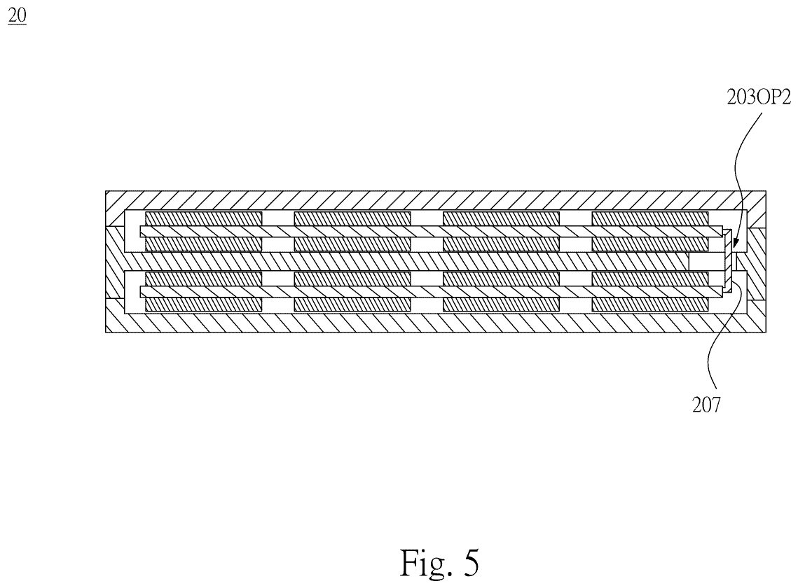

Please refer to FIGS. 4 and 5. FIG. 4 is a schematic diagram of a heat dissipation unit having an opening according to a preferred embodiment of the present disclosure, and FIG. 5 is a schematic diagram of a heat dissipation unit having an opening according to another preferred embodiment of the present disclosure. The heat dissipation unit 203 has an opening 203OP1, 203OP2. The hard drive device 20 further includes a first printed circuit board 204 and a second printed circuit board 205. The second printed circuit board 205 is electrically connected to the first printed circuit board 204 through at least one of a connector 206 and a flexible flat cable 207, wherein at least one of the connector 206 and the flexible flat cable 207 passes through the opening 203OP1, 203OP2.

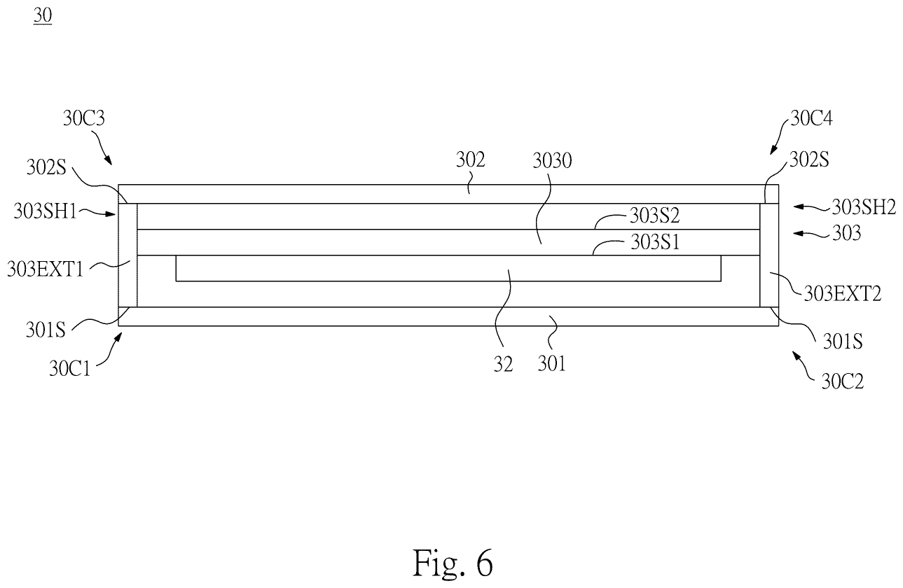

Please refer to FIG. 6, which is a schematic diagram of a hard drive device 30 according to another preferred embodiment of the present disclosure. The hard drive device 30 includes a first housing 301, a second housing 302, a heat dissipation unit 303 and at least one electronic component 32. The second housing 302 is disposed at a corresponding position of the first housing 301. The heat dissipation unit 303 has a first surface 303S1, a second surface 303S2, a first extension element 303EXT1, and a second extension element 303EXT2, wherein the at least one electronic component 32 is in contact with at least one of the first surface 303S1 and the second surface 303S2, the first extension element 303EXT1 is in contact with the first housing 301 and the second housing 302, the second extension element 303EXT2 is in contact with the first housing 301 and the second housing 302, and the first extension element 303EXT1 and the second extension element 303EXT2 serve as a third housing 303SH1, 303SH2 of the hard drive device 30.

In any embodiment of the present disclosure, the first extension element 103EXT1, 203EXT1, 303EXT1 can extend just to the corners 20C1, 20C2, 20C3, 20C4 of the hard drive device 10, 20, 30, without exceeding the corners 20C1, 20C2, 20C3, 20C4 of the hard drive device 10, 20, 30, or beyond the corners 20C1, 20C2, 20C3, 20C4 of the hard drive 10, 20, 30.

In any embodiment of the present disclosure, the heat dissipation unit 103, 203, 303, the first housing 101, 201, 301, and the second housing 102, 202, 303 are made of highly thermally conductive materials, such as metal, or can be housings with a heat dissipation effect. The at least one electronic component 32 is a heat-generating electronic component, which includes at least one of a processor chip, a memory chip, a power management chip, a communication chip, and an application specific integrated circuit (ASIC). The at least one electronic component 32 is in direct or indirect contact with at least one of the first surface 303S1 and the second surface 303S2 to conduct the heat of the at least one electronic component 32 from the at least one electronic component 32 to the heat dissipation unit 303. The first extension element 303EXT1 is in contact with the first housing 301 and the second housing 302, and the second extension element 303EXT2 is in contact with the first housing 301 and the second housing 302 to conduct the heat from at least one of the first surface 303S1 and the second surface 303S2 of the heat dissipation unit 303 to the first extension element 303EXT1 and the second extension element 303EXT2. The first extension element 303EXT1 and the second extension element 303EXT2 serve as a third housing 303SH1, 303SH2 of the hard drive device 30 so as to dissipate the heat through the third housing 303SH1, 303SH2. The first extension element 303EXT1 and the second extension element 303EXT2 are integrally formed with the heat dissipation unit 303.

In any embodiment of the present disclosure, there is a first thermal conductive element (not shown) between the heat dissipation unit 103, 203, 303 and the at least one electronic component 12, 16, 22, 24, 26, 28, 32. The first housing 101, 201, 301 and the second housing 102, 202, 302 respectively have a first connection surface 101S, 201S, 301S and a second connection surface 102S, 202S, 302S. There is a first thermal conductive element (not shown) between the first extension element 103EXT1, 203EXT1, 303EXT1 of the heat dissipation unit 103, 203, 303 and the first connection surface 101S, 201S, 301S and the second connection surface 102S, 202S, 302S. There is a second thermal conductive element (not shown) between the second extension element 103EXT2, 203EXT2, 303EXT2 of the heat dissipation unit 103, 203, 303 and the first connection surface 101S, 201S, 301S and the second connection surface 102S, 202S, 302S. The first thermal conductive element and the second thermal conductive element include a heat dissipation medium. In any embodiment of the present disclosure, the heat dissipation medium can be a heat dissipation medium such as heat dissipation paste, a heat dissipation pad, heat dissipation gel, etc.

In any embodiment of the present disclosure, the hard drive device 20, 30 has a first corner 20C1, 30C1 and a second corner 20C2, 30C2. The first extension element 203EXT1, 303EXT1 extends beyond the first corner 20C1, 30C1, and contacts the first connection surface 201S, 301S of the first housing 201, 301. The second extension element 203EXT2, 303EXT2 extends beyond the second corner 20C2, 30C2, and contacts the first connection surface 201S, 301S of the first housing 201, 301. The hard drive device 20, 30 has a third corner 20C3, 30C3 and a fourth corner 20C4, 30C4. The first extension element 203EXT1, 303EXT1 extends beyond the third corner 20C3, 30C3, and contacts the second connection surface 202S, 302S of the second housing 202, 302. The second extension element 203EXT2, 303EXT2 extends beyond the fourth corner 20C4, 30C4, and contacts the second connection surface 202S, 302S of the second housing 202, 302. The heat dissipation unit 203 has an opening 203OP1, 203OP2. The hard drive device 20, 30 further includes a first printed circuit board 204 and a second printed circuit board 205. The second printed circuit board 205 is connected to the first printed circuit board 204 through at least one of a connector 206 and a flexible cable 207, wherein at least one of the connector 206 and the flexible cable 207 passes through the opening 203OP1, 203OP2.

In any embodiment of the present disclosure, the heat dissipation unit 103, 203, 303 further includes a heat dissipation unit body 1030, 2030, and the heat dissipation unit body 1030, 2030 transfers a thermal energy from the at least one of the first and the second surfaces of the heat dissipation unit 103, 203, 303 to the first extension element 103EXT1, 203EXT1, 303EXT1 and the second extension element 103EXT2, 203EXT2, 303EXT2.

In any embodiment of the present disclosure, the third housing 103SH1, 103SH2, 203SH1, 203SH2, 303SH1, 303SH2 meets at least one of the following conditions: the third housing 103SH1, 103SH2, 203SH1, 203SH2, 303SH1, 303SH2 contacts at least one of the first housing 101, 201, 301 and the second housing 102, 202, 302 to dissipate a thermal energy from the at least one electronic component 12, 16, 22, 24, 26, 28, 32; and the third housing 103SH1, 103SH2, 203SH1, 203SH2, 303SH1, 303SH2 dissipates the thermal energy by an air flow path, wherein the air flow path is formed between the first extension element 103EXT1, 203EXT1, 303EXT1 and the second extension element 103EXT2, 203EXT2, 303EXT2.

In any embodiment of the present disclosure, the hard drive device 10, 20, 30 has a first and a second lateral portions HDL1, HDL2 and a first and a second plate portions HDP1, HDP2 as shown in FIG. 3A. The hard drive device 10, 20, 30 has a first corner 20C1 and a second corner 20C2. The first corner 20C1 is located between the first plate portion HDP1 and the first lateral portion HDL1. The second corner 20C2 is located between the first plate portion HDP1 and the second lateral portion HDL2. The first extension element 103EXT1, 203EXT1, 303EXT1, 203EXT3 extends beyond the first corner 20C1 to contact a first connecting surface 201S of the first housing 201. The second extension element 103EXT2, 203EXT2, 303EXT2, 203EXT4 extends beyond the second corner 20C2 to contact the first connection surface 201S of the first housing 201.

In any embodiment of the present disclosure, the hard drive device 10, 20,30 has a first and a second lateral portions HDL1, HDL2 and a first and a second plate portions HDP1M HDP2. The hard drive device 10, 20, 30 has a third corner 20C3 and a fourth corner 20C4. The third corner 20C3 is located between the second plate portion HDP2 and the first lateral portion HDL1. The fourth corner 20C4 is located between the second plate portion HDP2 and the second lateral portion HDL2. The first extension element 103EXT1, 203EXT1, 303EXT1, 203EXT3 extends beyond the third corner 20C3 to contact a second connecting surface 202S of the second housing 202. The second extension element 103EXT2, 203EXT2, 303EXT2, 203EXT4 extends beyond the fourth corner 20C4 to contact the second connection surface 202S of the second housing 202.

In any embodiment of the present disclosure, the first extension element 103EXT1, 203EXT1, 303EXT1, 203EXT3 and the second extension element 103EXT2, 203EXT2, 303EXT2, 203EXT4 extend from the heat dissipation unit body 1030, 2030, wherein the at least one electronic component 12, 16, 22, 24, 26, 28, 32 is in contact with the heat dissipation unit body 1030, 2030, 3030; the first extension element 103EXT1, 203EXT1, 303EXT1, 203EXT3 and the second extension element 103EXT2, 203EXT2, 303EXT2, 203EXT4 extend from the heat dissipation unit body 1030, 2030, 3030 to the first housing 101, 201, 301 and the second housing 102, 202, 302; and the first extension element 103EXT1, 203EXT1, 303EXT1, 203EXT3 and the second extension element 103EXT2, 203EXT2, 303EXT2, 203EXT4 serve as the third housing 103SH1, 103SH2, 203SH1, 203SH2, 303SH1, 303SH2 of the hard drive device 10, 20, 30.

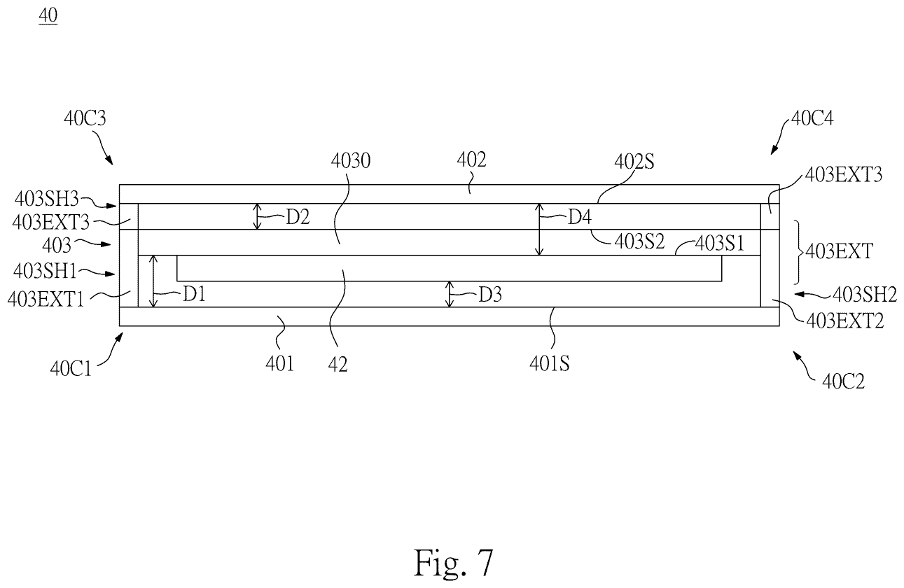

Please refer to FIG. 7, which is a schematic diagram of the heat dissipation unit 403 for the hard drive device 40 according to the preferred embodiment of the present disclosure. The hard drive device 40 includes at least one electronic component 42, a first housing 401, and a second housing 402. The heat dissipation unit 403 includes a heat dissipation unit body 4030 and at least one extension element 403EXT, including 403EXT1, 403EXT2, 403EXT3. At least one extension element 403EXT extends from the heat dissipation unit body 4030, wherein the at least one electronic component 42 is in contact with the heat dissipation unit body 4030. The at least one extension element 403EXT extends from the heat dissipation unit body 4030 to the first housing 401 and the second housing 402. The at least one extension element 403EXT serves as a third housing 403SH1, 403SH2, 403SH3 of the hard drive device 40.

In any embodiment of the present disclosure, the extension element 403EXT1 and the extension element 403EXT2 can be regarded as an annular extension element, and the extension element 403EXT3 can contact the connection surface 402S of the second housing 402. For example, the extension element 403EXT3 contacts the entire connection surface 402S. The heat dissipation unit body 4030 has a distance D1 from the first housing 401 and, and a distance D2 from the second housing 402 without contacting the first housing 401 and the second housing 402. The at least one electronic component 42 has a distance D3 from the first housing 401, and a distance D4 from the second housing 402 without contacting the first housing 401 and the second housing 402. The at least one extension element 403EXT is in contact with the first housing 401 and the second housing 402. For example, the extension element 403EXT1 and the extension element 403EXT2 are in contact with the first housing 401, and the extension element 403EXT3 is in contact with the second housing 402.

In any embodiment of the present disclosure, the heat dissipation unit body 4030 has a first surface 403S1 and a second surface 403S2. The at least one electronic component 42 includes a first electronic component 22, 42 and a second electronic component 24. The first surface 403S1 is in direct or indirect contact with the first electronic component 22, 42, and the second surface 403S2 is in direct or indirect contact with the second electronic components 24. The at least one electronic component 12, 16, 22, 24, 26, 28, 32, 42 is at least one of a processor chip, a memory chip, a power management chip, a communication chip, and an application specific integrated circuit (ASIC). The at least one extension element 403EXT includes a circumferential extension element surrounding the heat dissipation body 4030. For example, the extension element 403EXT1 and the extension element 403EXT2 can be regarded as the same circumferential extension element, and another extension element 403EXT3 can be regarded as another circumferential extension element. Alternatively, the at least one extension element 403EXT includes a plurality of extension elements 403EXT1, 403EXT2, 403EXT3. The extension elements 403EXT1, 403EXT2, 403EXT3 are integrally formed with the heat dissipation body 4030. The plurality of extension elements 403EXT1, 403EXT2, 403EXT3 are in contact with the first housing 401 and the second housing 402. For example, the extension elements 403EXT1, 403EXT2 are in contact with the first housing 401 and the second housing 402, and the extension element 403EXT3 is in contact with the second housing 402. There is a first thermal conductive element (not shown) between the heat dissipation unit 103, 203, 303403 and the at least one electronic component 12, 16, 22, 24, 26, 28, 32, 42. The first housing 401 and the second housing 402 respectively have a first connection surface 401S and a second connection surface 402S. There is a second thermal conductive element (not shown) between the plurality of extension elements 403EXT1, 403EXT2, 403EXT3 of the heat dissipation unit 403 and the first connection surface 401S and the second connection surface 402S. The first thermal conductive element and the second thermal conductive element include a heat dissipation medium. The hard drive device 40 has a first corner 40C1 and a second corner 40C2. The extension element 403EXT1 extends beyond the first corner 40C1, and contacts the first connection surface 401S of the first housing 401. The extension element 403EXT2 extends beyond the second corner 40C2, and contacts the first connection surface 401S of the first housing 401. The hard drive device 40 has a third corner 40C3 and a fourth corner 40C4. The extension element 403EXT1 extends beyond the third corner 40C3, and contacts the second connection surface 402S of the second housing 402. The extension element 403EXT2 extends beyond the fourth corner 40C4, and contacts the second connection surface 402S of the second housing 402. The heat dissipation unit 40 has an opening 203OP1, 203OP2. The hard drive device 10, 20, 30, 40 further includes a first printed circuit board 204 and a second printed circuit board 205. The second printed circuit board 205 is electrically connected to the first printed circuit board 204 through at least one of a connector 206 and a flexible cable 207, wherein at least one of the connector 206 and the flexible cable 207 passes through the opening 203OP1, 203OP2.

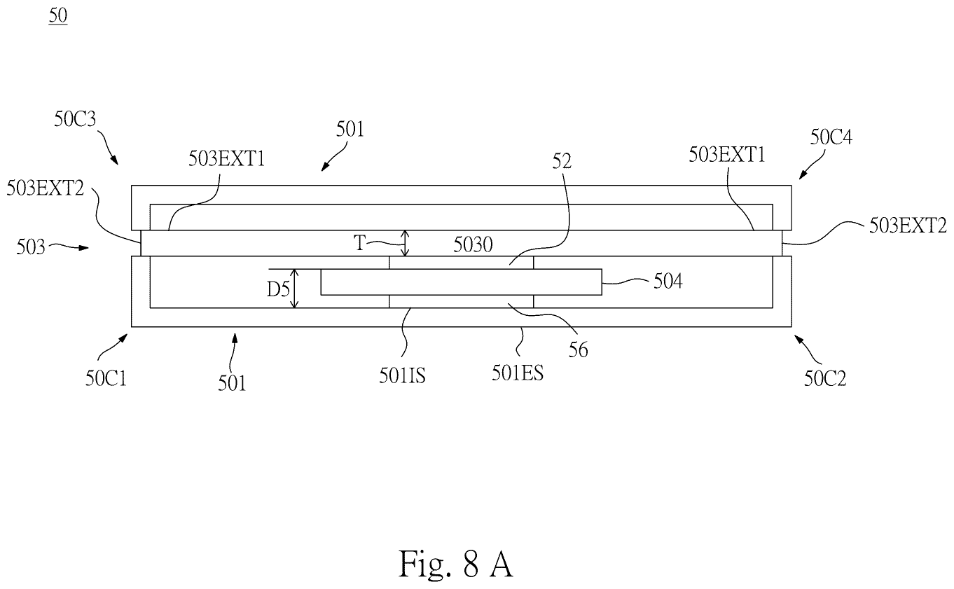

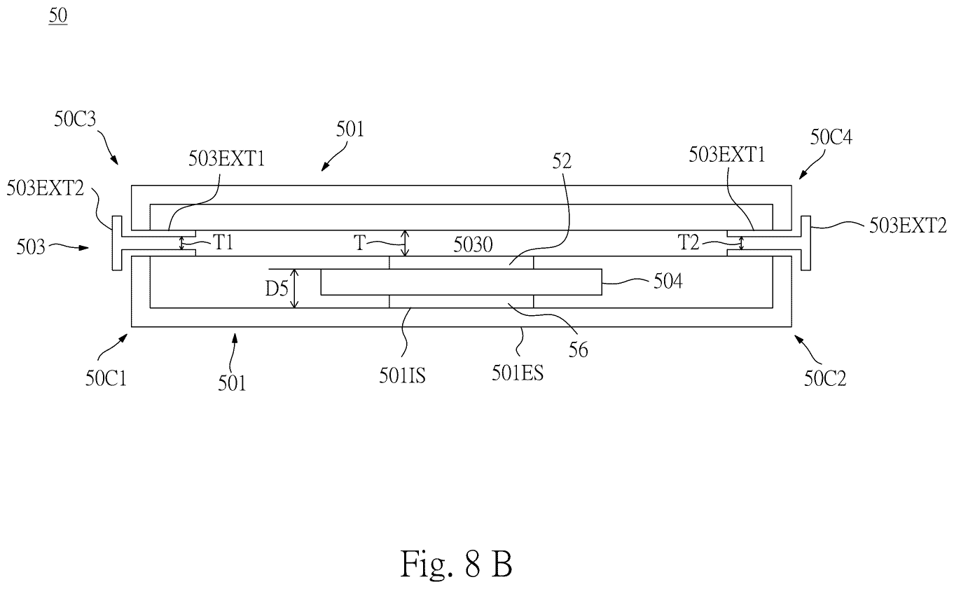

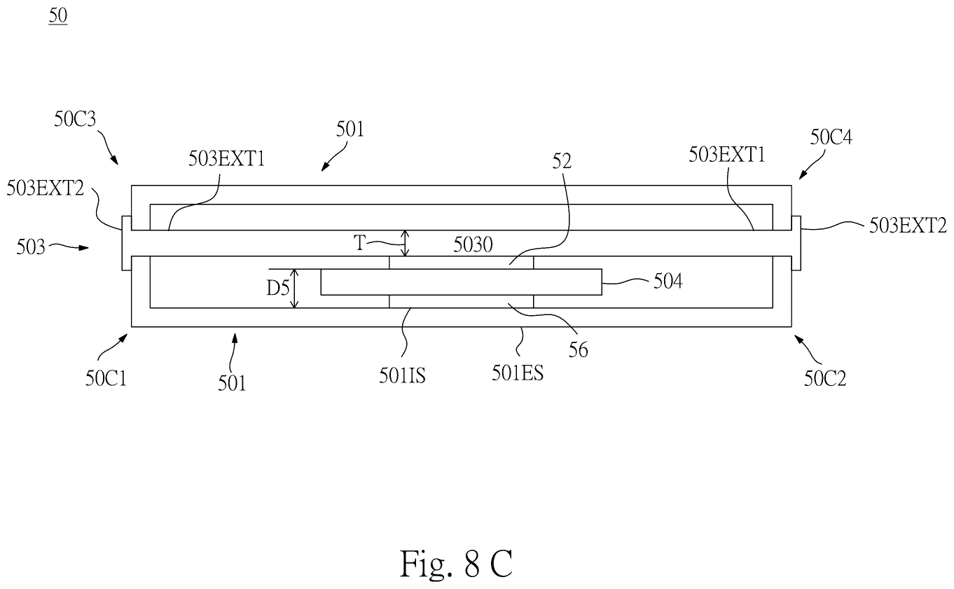

Please refer to FIG. 8A, which is a schematic diagram of a heat dissipation unit 503 for a hard drive device 50 according to another preferred embodiment of the present disclosure. The hard drive device 50 includes a printed circuit board 504, two heat-generating electronic components 52, 56 respectively disposed on both sides of the printed circuit board 504, and a housing 501 contacting one heat-generating electronic component 56 of the two heat-generating electronic components 52, 56. The housing 501 has an inner surface 501IS and an outer surface 501ES. There is a distance D5 between the other heat-generating electronic component 52 of the two heating electronic components 52, 56 and the inner surface 501IS. The heat dissipation unit 503 includes a heat dissipation unit body 5030, which is in contact with the other heat-generating electronic component 52, and extends beyond the inner surface 501IS.

In any embodiment of the present disclosure, the other heat-generating electronic component 52 is in direct contact with the heat dissipation unit 503, or in indirect contact with the heat dissipation unit 503 through a thermal conductive element (not shown). The heat dissipation unit 503 has an extension portion 503EXT1, which is in contact with the housing 501.

Please refer to FIG. 8B, which is a schematic diagram of another embodiment of the heat dissipation unit 503 according to FIG. 8A. The thicknesses T1 and T2 of the extension portion 503EXT2 in FIG. 8B are smaller than the thickness T of the heat dissipation unit body 5030, and the extension portion 503EXT2 does not contact the housing 501. In this embodiment, the heat dissipation unit 503 can guide the hot airflow.

Please refer to FIG. 8C, which is a schematic diagram of another embodiment of the heat dissipation unit 503 according to FIG. 8B. The thicknesses T1 and T2 of the extension portion 503EXT2 in FIG. 8C are equal to the thickness T of the heat dissipation unit body 5030, and the extension portion 503EXT2 contacts the housing 501. In this embodiment, the heat dissipation unit 503 can conduct the hot airflow in a contact manner.

In any embodiment of the present disclosure, the thermal conductive element includes a heat dissipation medium. The housing 501 has at least one corner 50C1, 50C2, 50C3, 50C4, and the extension portion 503EXT of the heat dissipation unit 503 extends to the at least one corner 50C1, 50C2, 50C3, 50C4. The heat dissipation unit 503 has an opening 203OP1, 203OP2. The hard drive device 50 further includes another printed circuit board 205. The another printed circuit board 205 is electrically connected to the printed circuit board 204 through at least one of a connector 206 and a flexible cable 207, wherein at least one of the connector 206 and the flexible cable 207 passes through the opening 203OP1 and 203OP2. The housing 501 can be a heat-dissipating housing made of a heat-dissipating material, such as a metal housing, or can be a housing having a heat-dissipating effect. The housing 501 can also be a housing that generally does not have heat dissipation materials. In this situation, the airflow circulation manner can be used to dissipate heat.

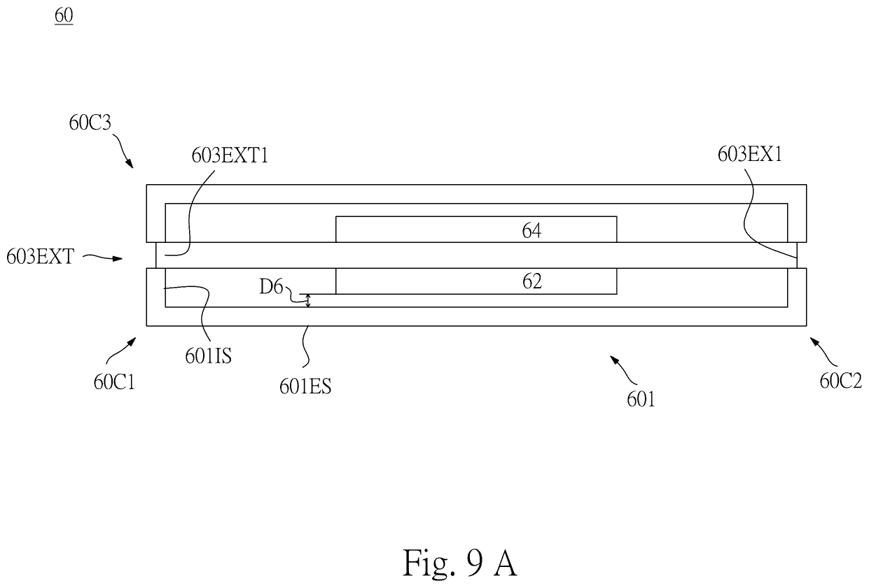

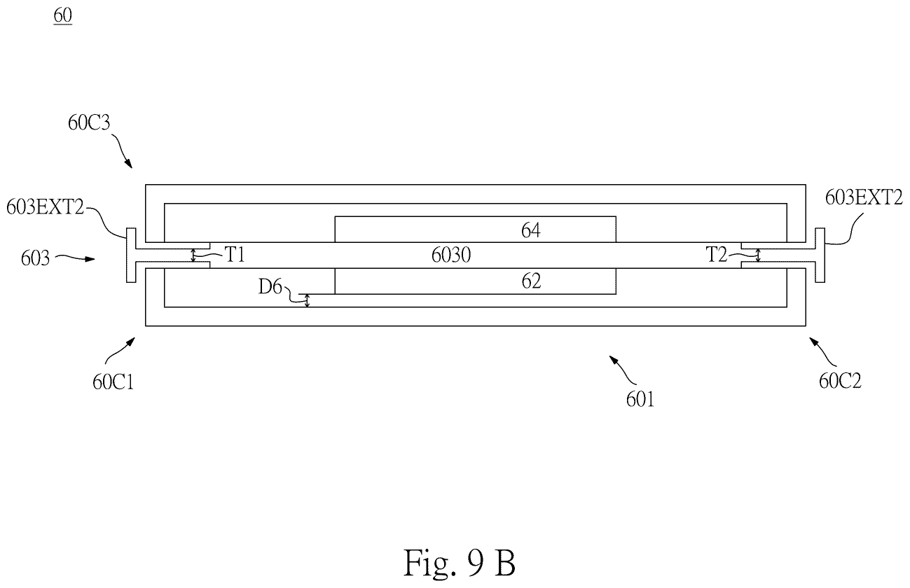

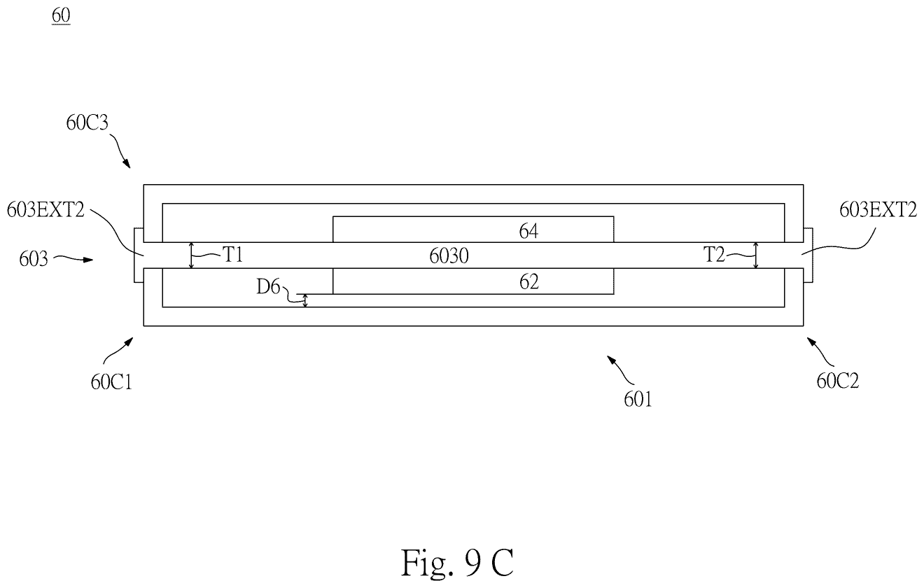

Please refer to FIG. 9A, which is a schematic diagram of a heat dissipation unit 603 for a hard drive device 60 according to another preferred embodiment of the present disclosure, wherein the hard drive device 60 has a housing 601 and a plurality of internal heat-generating electronic components 62, 64. There is a distance D6 between at least one of the plurality of internal heat-generating electronic components 62, 64 and the housing 601. The housing 601 has an inner surface 601IS and an outer surface 601ES. The heat dissipation unit 603 is an intermediate extension member 603EXT, which is in contact with at least one of the plurality of internal heat-generating electronic components 62, 64, and extends beyond the inner surface 601IS.

Please refer to FIG. 9B, which is a schematic diagram of another embodiment of the heat dissipation unit 603 according to FIG. 9A. The thicknesses T1 and T2 of the extension portion 603EXT2 are smaller than the thickness T of the heat dissipation unit body 6030, and the extension portion 603EXT2 does not contact the housing 601. In this embodiment, the heat dissipation unit 603 can guide the hot airflow.

Please refer to FIG. 9C, which is a schematic diagram of another embodiment of the heat dissipation unit 603 according to FIG. 9B. The thicknesses T1 and T2 of the extension portion 603EXT2 are equal to the thickness T of the heat dissipation unit body 6030, and the extension portion 603EXT2 contacts the housing 601. In this embodiment, the heat dissipation unit 603 can conduct the hot airflow in a contact manner.

The plurality of internal heat-generating electronic components 62, 64 are in direct contact with the heat dissipation unit 603, or are in indirect contact with the heat dissipation unit 603 through a heat conductive element (not shown). The heat conductive element contains a heat dissipation medium. The housing 601 has at least one corner 60C1, 60C2, 60C3, 60C4, and the middle extension member 603EXT of the heat dissipation unit 603 extends to the at least one corner 60C1, 60C2, 60C3, 60C4. The heat dissipation unit 603 has an opening 203OP1, 203OP2. The hard drive device 60 includes a printed circuit board 204. The printed circuit board 204 is electrically connected to the plurality of internal heat-generating electronic components 62, 64, and connected to another printed circuit board through at least one of a connector 206 and a flexible cable 207, wherein at least one of the connector 206 and the flexible cable 207 passes through the opening 203OP1, 203OP2.

While the invention has been described in terms of what is presently considered to be the most practical and preferred embodiments, it is to be understood that the invention need not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A hard drive device comprising:
a device body;
a first housing configured on the device body;
a second housing configured opposite to the first housing;
a heat dissipation unit having a first surface, a second surface, a first extension element and a second extension element; and
at least one electronic component in contact with at least one of the first surface and the second surface, wherein:
the first extension element is in contact with the first housing and the second housing, and the second extension element is in contact with the first housing and the second housing; and
the first extension element and the second extension element serve as a third housing of the hard drive device.

2. The hard drive device as claimed in claim 1, wherein:
the at least one electronic component is a heat-generating electronic component, and includes at least one of a processor chip, a memory chip, a power management chip, a communication chip and an application specific integrated circuit (ASIC).

3. The hard drive device as claimed in claim 1, wherein:
the at least one electronic component directly or indirectly contacts with at least one of the first surface and the second surface to transfer a thermal energy generated by the at least one electronic component to the heat dissipation unit.

4. The hard drive device as claimed in claim 1, wherein:
the heat dissipation unit further includes a heat dissipation unit body; and
the heat dissipation unit transfers a thermal energy from the at least one of the first and the second surfaces of the heat dissipation unit to the first extension element and the second extension element.

5. The hard drive device as claimed in claim 1, wherein the third housing meets at least one of the following conditions:
the third housing contacts with at least one of the first housing and the second housing to dissipate a thermal energy from the at least one electronic component; and
the third housing dissipates the thermal energy by an air flow path, wherein the air flow path is formed between the first extension element and the second extension element.

6. The hard drive device as claimed in claim 1, wherein:
the first extension element and the second extension element are integrally formed in the heat dissipation unit;
a first heat transfer element is disposed between the heat dissipation unit and the at least one electronic component; and
the first heat transfer element includes a heat dissipation medium.

7. The hard drive device as claimed in claim 1, wherein:
the first housing and the second housing respectively have a first connection surface and a second connection surface;
the first extension element directly or indirect contacts with the first connection surface and the second connection surface, and the second extension element directly or indirectly contacts with the first connection surface and the second connection surface;
there are a plurality of second heat transfer elements, each of which is disposed between either of the first extension element and the second extension element of the heat dissipation unit and either of the first connection surface, and the second connection surface; and
the second heat transfer element includes a heat dissipation medium.

8. The hard drive device as claimed in claim 1, wherein:
the hard drive device has a first and a second lateral portions and a first and a second plate portions;
the hard drive device has a first corner and a second corner;
the first corner is located between the first plate portion and the first lateral portion;
the second corner is located between the first plate portion and the second lateral portion;
the first extension element extends beyond the first corner to contact with a first connecting surface of the first housing; and
the second extension element extends beyond the second corner to contact with the first connection surface of the first housing.

9. The hard drive device as claimed in claim 1, wherein:
the hard drive device has a first and a second lateral portions and a first and a second plate portions;
the hard drive device has a third corner and a fourth corner;
the third corner is located between the second plate portion and the first lateral portion;
the fourth corner is located between the second plate portion and the second lateral portion;
the first extension element extends beyond the third corner to contact with a second connecting surface of the second housing; and
the second extension element extends beyond the fourth corner to contact with the second connection surface of the second housing.

10. The hard drive device as claimed in claim 1, wherein:
the heat dissipation unit has an opening; and
the hard drive further includes:
a first printed circuit board; and
a second printed circuit board electrically connected to the first printed circuit board through at least one of a connector and a flexible flat cable, wherein the at least one of the connector and the flexible flat cable passes through the opening.

11. The hard drive device as claimed in claim 1, wherein:
the heat dissipation unit includes:
a heat dissipation unit body; and
the first and second extension elements extended from the heat dissipation unit body, wherein:
the at least one electronic component is in contact with the heat dissipation unit body;
the first and second extension elements extend from the heat dissipation unit body to the first housing and the second housing; and
the first and second extension elements serve as the third housing of the hard drive device.

12. The hard drive device as claimed in claim 11, wherein:
the first and second extension elements may alternatively be an integral circumferential extension element surrounding the heat dissipation unit body
on the condition of being the surrounding extension element, it is integrally formed with the heat dissipation body; and
on the condition of being two separate extension elements, they are in contact with the first housing and the second housing respectively.

13. The hard drive device as claimed in claim 11, wherein:
the heat dissipation unit body falls short of contacting with the first housing and the second housing; and
the at least one electronic component falls short of contacting with the first housing and the second housing.

14. A heat dissipation unit for a hard drive device, wherein:
the hard drive device includes a device printed circuit board, a first and a second heat-generating electronic components respectively disposed on both sides of the printed circuit board, and a housing in contact with the first heat-generating electronic components;
the housing has an inner surface and an outer surface;
a distance exists between the second heat-generating electronic components and the inner surface; and
the heat dissipation unit comprises a heat dissipation unit body in contact with the second heat-generating electronic component and extending beyond the inner surface.

15. The heat dissipation unit as claimed in claim 14, wherein:
the second heat-generating electronic components directly contacts with the heat dissipation unit, or indirectly contacts with the heat dissipation unit through a heat transfer element;
the heat dissipation unit has an extension portion, and the extension portion is in contact with the housing; and
the heat transfer element includes a heat dissipation medium.

16. The heat dissipation unit as claimed in claim 14, wherein:
the hard drive device has a plurality of lateral portions and a plurality of plate portions; the hard drive device has at least one corner located between the plurality of plate portions and the plurality of lateral portions, and the extension portion of the heat dissipation unit extends from the heat dissipation unit body to the at least one corner.

17. The heat dissipation unit as claimed in claim 14, wherein:
the heat dissipation unit has an opening; and
the hard drive device further comprises:
a second printed circuit board electrically connected to the device printed circuit board through at least one of a connector and a flexible flat cable, wherein the at least one of the connector and the flexible flat cable passes through the opening.

18. A heat dissipation unit for a hard drive device, wherein:
the hard drive device has a housing and a plurality of internal heat-generating electronic components;
a distance exists between at least one of the plurality of internal heating electronic components and the housing;
the housing has an inner surface and an outer surface; and
the heat dissipation unit is an intermediate extension member contacting with at least one of the plurality of internal heat-generating electronic components and extending beyond the inner surface.

19. The heat dissipation unit as claimed in claim 18, wherein:
the intermediate extension member is in contact with the housing;
the plurality of internal heat-generating electronic components directly contact with the heat dissipation unit, or indirectly contact with the heat dissipation unit through a heat transfer element; and
the heat transfer element includes a heat dissipation medium.

20. The heat dissipation unit as claimed in claim 18, wherein:
the hard drive device has a plurality of lateral portions and a plurality of plate portions;
the heat dissipation unit has a heat dissipation unit body;
the hard drive device has at least one corner located between the plurality of plate portions and the plurality of lateral portions, and the intermediate extension member of the heat dissipation unit extends from the heat dissipation unit body to the at least one corner;
the heat dissipation unit has an opening; and
the hard drive device includes:
a printed circuit board electrically connected to the plurality of heat-generating electronic components, and is electrically connected to a second printed circuit board through at least one of a connector and a flexible flat cable, wherein the at least one of the connector and the flexible flat cable passes through the opening.
